(19) United States
(12) Patent Application Publication
(10) Pub. No.: US 2015/0014839 A1
(43) Pub. Date: Jan. 15, 2015

(54) Electronic Element Packaging Structure and Carrier Substrate Thereof

(71) Applicant: Lighten Corporation, Zhongli City (TW)

(72) Inventor: Shu-Mei KU, Zhongli City (TW)

(21) Appl. No.: 14/326,980

(22) Filed: Jul. 9, 2014

(30) Foreign Application Priority Data
Jul. 9, 2013 (TW) 102124492

(51) Int. Cl. H01L 23/467; H01L 23/373; H01L 33/64; H01L 23/36

(52) U.S. Cl. CPC H01L 23/467; H01L 23/36; H01L 23/3735; H01L 33/642
USPC 257/706

(57) ABSTRACT

The present invention discloses an electronic element packaging structure and a carrier substrate thereof. The electronic element packaging structure includes a heat conduction substrate, which is a vapor chamber having a vacuum cavity thereinside or a heat pipe; a circuit layer disposed on the heat conduction substrate, insulated from the heat conduction substrate, and exposing the upper surface of the heat conduction substrate; at least one chip directly disposed on the upper surface of the heat conduction substrate; an electric connection structure electrically connecting the chip and the circuit layer; and an encapsulant covering the chip and the electric connection structure.

### BACKGROUND OF THE INVENTION

1. Field of the Invention

The present invention relates to a semiconductor packaging technology, particularly to an electronic element packaging structure and a carrier substrate thereof.

2. Description of the Prior Art

In a semiconductor packaging structure, if the heat generated by the packaged electronic element cannot radiate fast, the temperature of the element will rise rapidly, and the reliability thereof will degrade. If heat cannot radiate fast from the packaging structure of a light emitting diode (LED), the service life thereof will decrease. Therefore, heat radiation is a critical problem in the packaging technology of electronic elements.

### SUMMARY OF THE INVENTION

One objective of the present invention is to provide an electronic element packaging structure and a carrier substrate thereof, wherein a vapor chamber having a vacuum cavity thereinside or a heat pipe is used as the primary packaging substrate, and wherein the electronic element is directly disposed on the vapor chamber or the heat pipe to fast radiate heat and avoid heat accumulation.

The present invention proposes an electronic element packaging structure, which includes a heat conduction substrate, which is a vapor chamber having a vacuum cavity thereinside or a heat pipe; a circuit layer disposed on the heat conduction substrate, insulated from the heat conduction substrate, and exposing the upper surface of the heat conduction substrate; at least one chip directly disposed on the upper surface of the heat conduction substrate; an electric connection structure electrically connecting the chip and the circuit layer; and an encapsulant covering the chip and the electric connection structure.

The present invention also proposes a carrier substrate for an electronic element packaging structure, which includes a heat conduction substrate, which is a vapor chamber having a vacuum cavity thereinside or a heat pipe; and a circuit layer disposed on the heat conduction substrate, insulated from the heat conduction substrate, and exposing the upper surface of the heat conduction substrate, wherein at least one chip is directly disposed on the exposed upper surface of the heat conduction substrate, and wherein at least one passive element is selectively disposed on the circuit layer.

Below, embodiments are described in detail in cooperation with the attached drawings to make easily understood the objectives, technical contents, characteristics and accomplishments of the present invention.

### BRIEF DESCRIPTION OF THE DRAWINGS

FIG. 1 is a sectional view schematically showing an electronic element packaging structure according to one embodiment of the present invention;

FIG. 2A and FIG. 2B are sectional views respectively showing heat conduction substrates according to different embodiments of the present invention;

FIG. 3 is a diagram schematically showing an electronic element packaging structure according to one embodiment of the present invention;

FIG. 4A is a sectional view showing a circuit layer according to one embodiment of the present invention;

FIG. 4B is a sectional view showing a circuit layer according to another embodiment of the present invention; and

FIG. 5 is a sectional view schematically showing an electronic element packaging structure according to another embodiment of the present invention.

### DESCRIPTION OF THE PREFERRED EMBODIMENT

Embodiments are used to demonstrate the present invention below. However, these embodiments are only to exemplify the present invention but not to limit the scope of the present invention.

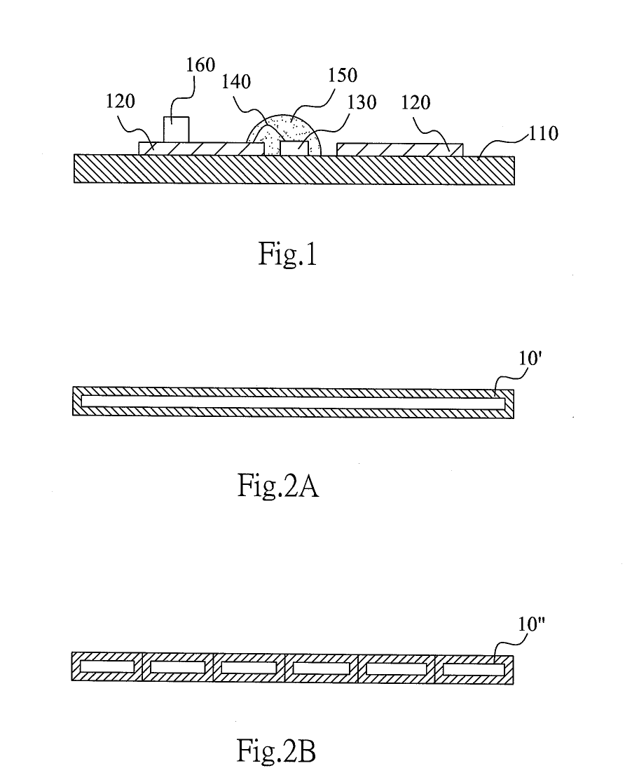

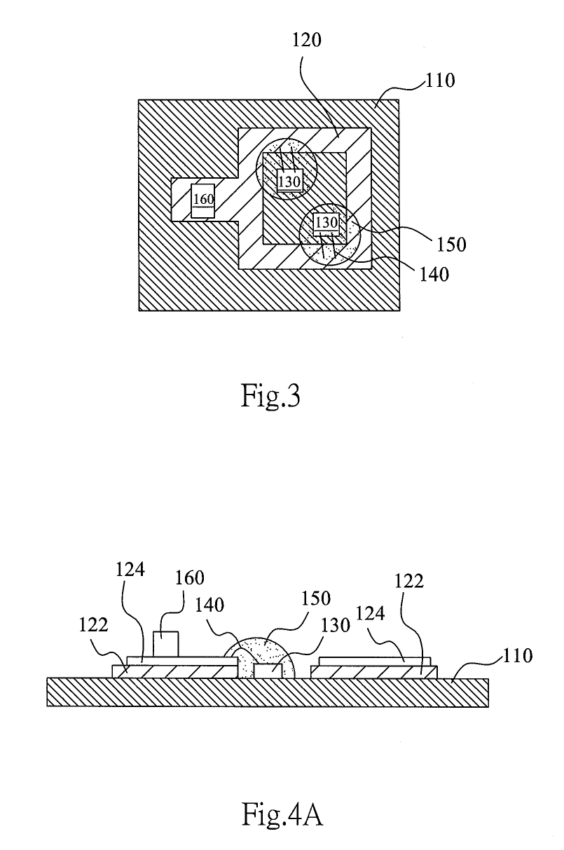

Refer to FIG. 1 and FIG. 3. In one embodiment, the electronic element packaging structure of the present invention at least includes a heat conduction substrate 110, a circuit layer 120, at least one chip 130, an electric connection structure 140, an encapsulant 150, and at least one passive element 160. In this embodiment, the heat conduction substrate 110 is a vapor chamber having a vacuum cavity thereinside or a heat pipe; the circuit layer 120 is disposed on and insulated from the heat conduction substrate 110 and exposes the upper surface of the heat conduction substrate 110; the chip 130 is directly disposed on the upper surface of the heat conduction substrate 110; the electric connection structure 140 is in form of wires and used to electrically connect the chip 130 and the circuit layer 120; the encapsulant 150 covers the chip 120 and the electric connection structure 140

In one embodiment, the heat generated by the electronic element, such as the chip 130, is fast conducted elsewhere by the heat conduction substrate 110. The heat conduction substrate 110 is made of a metallic material or a high thermal-conductivity material. Refer to FIG. 2A and FIG. 2B. In one embodiment, the heat conduction substrate 110 is a vapor chamber 10′ having a vacuum cavity thereinside or a heat pipe 10″, which is able to conduct heat rapidly. The electronic element may also be a bare die, in addition to being a chip. Thereby, the electronic element packaging structure of the present invention can realize the second level packaging and the third level packaging simultaneously and promote the heat radiation efficiency thereof.

Refer to FIG. 1 and FIG. 3 again. In one embodiment, the passive element 160 is disposed on the circuit layer 120.

Refer to FIG. 3 again. In one embodiment, the passive element 160 of the electronic element packaging structure of the present invention is a thermistor detecting whether the electronic element packaging structure overheats and triggering the protection circuit of the circuit layer 120 to protect the system.

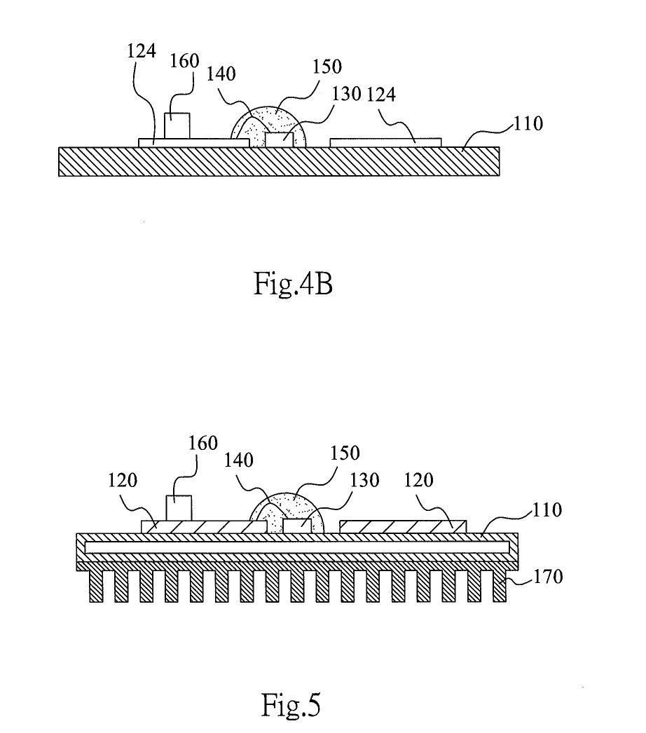

Refer to FIG. 4A. In one embodiment, the circuit layer 120 is a circuit substrate 122 having a patterned circuit 124 thereon. Refer to FIG. 4B. In one embodiment, the circuit layer 120 is directly fabricated into a patterned circuit 124. In one embodiment, the circuit substrate 122 is a copper-foil substrate, an insulating substrate, a glass-fiber substrate, a ceramic substrate, a glass-fiber prepreg, a polymeric substrate, or a flexible substrate.

Refer to FIG. 5. In one embodiment, the electronic element packaging structure of the present invention further includes a heat radiation element 170 arranged below the heat conduction substrate 110. The heat conduction substrate 110 conducts heat to the heat radiation element 170, and the heat radiation element 170 radiates the heat. In one embodiment, the heat radiation element 170 is a group of heat radiation fins.

Refer to FIG. 3 again. In one embodiment, the carrier substrate for the electronic element packaging structure of the present invention includes a heat conduction substrate 110, which is a vapor chamber having a vacuum cavity thereinside or a heat pipe; and a circuit layer 120 disposed on and insulated from the heat conduction substrate 110 and exposing the upper surface of the heat conduction substrate 110, wherein at least one chip 130 is directly disposed on the exposed upper surface of the heat conduction substrate 110, and wherein at least one passive element 160 is selectively disposed on the circuit layer 120.

In one embodiment, the heat conduction substrate 110 of the carrier substrate of the present invention is made of a metallic material or a high thermal conductivity material. In one embodiment, the circuit layer 120 of the carrier substrate of the present invention is a patterned circuit 124, as shown in FIG. 4B. In one embodiment, the circuit layer 120 of the carrier substrate of the present invention is a circuit substrate 122 having a patterned circuit 124 thereon, as shown in FIG. 4A. In one embodiment, the circuit substrate 122 of the carrier substrate of the present invention is a copper-foil substrate, an insulating substrate, a glass-fiber substrate, a ceramic substrate, a glass-fiber prepreg, a polymeric substrate, or a flexible substrate. In one embodiment, the carrier substrate of the electronic element packaging structure of the present invention further includes a heat radiation element 170 arranged below the heat conduction substrate 110, as shown in FIG. 5. In one embodiment, the heat radiation element 170 of the carrier substrate of the present invention is a group of heat radiation fins.

In conclusion, the present invention is characterized in using a vapor chamber or a heat pipe as the primary packaging substrate and directly disposing the electronic elements on the vapor chamber or the heat pipe to fast dissipate the heat generated by the electronic elements and avoid heat accumulation. In the present invention, the circuit layer is disposed on and insulated from the heat conduction substrate and exposes the upper surface of the heat conduction substrate, and the chip is directly disposed on the upper surface of the heat conduction substrate. Thereby, the heat generated by the chip or other electronic elements would be rapidly conducted elsewhere by the heat conduction substrate. In the present invention, the circuit layer exposes the upper surface of the heat conduction substrate, which means that the size of the heat conduction substrate is greater than that of the circuit layer, whereby the heat conduction area is effectively increased. Thus, the heat generated by the circuit layer can also be rapidly conducted elsewhere. In the conventional technology, heat must be conducted through the encapsulant, the adhesive layer, and then the substrate. In the present invention, only an adhesive layer is interposed between the heat conduction substrate and the chip or bare die. Therefore, the heat generated by the chip or bare die can be directly conducted elsewhere by the heat conduction substrate.

The embodiments have been described in detail to fully demonstrate the characteristics and spirit of the present invention. However, these embodiments are only used to exemplify the present invention but not intended to limit the scope of the present invention. The present invention should be interpreted in the broadest sense to include all the equivalent modifications and variations according to the characteristic or spirit of the present invention.

What is claimed is:

1. An electronic element packaging structure comprising
a heat conduction substrate, which is a vapor chamber having a vacuum cavity thereinside or a heat pipe;
a circuit layer disposed on said heat conduction substrate, insulated from said heat conduction substrate, and exposing an upper surface of said heat conduction substrate;
at least one chip directly disposed on said upper surface of said heat conduction substrate;
an electric connection structure electrically connecting said chip and said circuit layer; and
an encapsulant covering said chip and said electric connection structure.

2. The electronic element packaging structure according to claim 1, wherein said heat conduction substrate is made of a metallic material or a high thermal conductivity material.

3. The electronic element packaging structure according to claim 1, wherein said circuit layer is a patterned circuit.

4. The electronic element packaging structure according to claim 1, wherein said circuit layer is a circuit substrate having a patterned circuit thereon.

5. The electronic element packaging structure according to claim 4, wherein said circuit layer is a copper-foil substrate, an insulating substrate, a glass-fiber substrate, a ceramic substrate, a glass-fiber prepreg, a polymeric substrate, or a flexible substrate.

6. The electronic element packaging structure according to claim 1 further comprising a heat radiation element arranged below said heat conduction substrate.

7. The electronic element packaging structure according to claim 6, wherein said heat radiation element is a group of heat radiation fins.

8. The electronic element packaging structure according to claim 1 further comprising at least one passive element disposed on said circuit layer.

9. The electronic element packaging structure according to claim 8, wherein said passive element is a thermistor used to detect whether said electronic element packaging structure overheats.

10. A carrier substrate for an electronic element packaging structure, comprising
a heat conduction substrate, which is a vapor chamber having a vacuum cavity thereinside or a heat pipe; and
a circuit layer disposed on said heat conduction substrate, insulated from said heat conduction substrate, and exposing an upper surface of said heat conduction substrate, wherein at least one chip is directly disposed on said upper surface of said heat conduction substrate, which is exposed by said circuit layer, and wherein at least one passive element is selectively disposed on said circuit layer.

11. The carrier substrate for an electronic element packaging structure according to claim 10, wherein said heat conduction substrate is made of a metallic material or a high thermal conductivity material.

12. The carrier substrate for an electronic element packaging structure according to claim 10, wherein said circuit layer is a patterned circuit.

13. The carrier substrate for an electronic element packaging structure according to claim 10, wherein said circuit layer is a circuit substrate having a patterned circuit thereon.

14. The carrier substrate for an electronic element packaging structure according to claim 13, wherein said circuit layer is a copper-foil substrate, an insulating substrate, a glass-fiber substrate, a ceramic substrate, a glass-fiber prepreg, a polymeric substrate, or a flexible substrate.

15. The carrier substrate for an electronic element packaging structure according to claim 10 further comprising a heat radiation element arranged below said heat conduction substrate.

16. The carrier substrate for an electronic element packaging structure according to claim 15, wherein said heat radiation element is a group of heat radiation fins.
